(19) United States
(12) Patent Application Publication
(10) Pub. No.: US 2006/0091566 A1
(43) Pub. Date: May 4, 2006

(54) Bond pad structure for integrated circuit chip

(76) Inventors: Chin-Tien Yang, Hsin-Chu (TW); Shou Zen Chang, Hsin-Chu (TW); Min Cao, Hsin-Chu (TW); Yuh-Jier Mii, Hsin-Chu (TW)

Correspondence Address: SLATER & MATSIL, L.L.P., 17950 PRESTON ROAD, SUITE 1000, DALLAS, TX, 75252, US

(21) Appl. No.: 10/989,481

(22) Filed: Nov. 16, 2004

Related U.S. Application Data
(60) Provisional application No. 60/624,284, filed on Nov. 2, 2004.

(51) Int. Cl. H01L 23/48

(52) U.S. Cl. 257/786

(57) ABSTRACT

An integrated circuit chip is provided, which includes a bond pad structure, a low-k dielectric layer, and active circuits. The bond pad structure includes a conductive bond pad, an Mₜₒₚ solid conductive plate, and an Mₜₒₚ₋₁ solid conductive plate. The Mₜₒₚ solid conductive plate is located under the bond pad. The Mₜₒₚ plate is electrically coupled to the bond pad. The Mₜₒₚ₋₁ solid conductive plate is located under the Mₜₒₚ plate. A low-k dielectric layer is located under the bond pad of the bond pad structure. At least part of an active circuit is located under the bond pad of the bond pad structure.

This application claims the benefit of U.S. Provisional Application No. 60/624,284, filed on Nov. 2, 2004, entitled Bond Pad Structure For Integrated Circuit Chip, which application is hereby incorporated herein by reference.

### TECHNICAL FIELD

The present invention generally relates to bond pad structures and metallization layers for integrated circuit chips.

### BACKGROUND

Integrated circuit (IC) chips are often electrically connected by wires (e.g., gold or aluminum wires) to a leadframe or a substrate in a packaging assembly to provide external signal exchange. Such wires are typically wire bonded to bond pads formed on an IC chip using thermal compression and/or ultrasonic vibration. A wire bonding process exerts thermal and mechanical stresses on a bond pad and on the underlying layers and structure below the bond pad. The bond pad structure needs to be able to sustain these stresses to ensure a good bonding of the wire.

Prior bond pad structures were fabricated from the bottom to the top layers, which did not allow metal wiring circuitry and semiconductor devices to pass under or be located below the bond pad structure. For a more efficient use of chip area or to reduce the chip size, it is desirable to form semiconductor devices and metal wiring circuitry under the bond pad. This is sometimes referred to as bond over active circuits (BOAC). At the same time, many processes now use low-k and ultra low-k dielectric materials for the intermetal dielectric (IMD) layers to reduce RC delay and parasitic capacitances. The general trend in IMD designs is that the dielectric constant (k) tends to decrease from the top downward toward the substrate. However, as the dielectric constant (k) decreases, typically the strength of the dielectric material decreases (as a general rule). Hence, many low-k dielectric materials are highly susceptible to cracking or lack strength needed to withstand some mechanical processes (e.g., wire bonding, CMP). Thus, a need exists for a bond pad structure that can sustain and better disperse the stresses exerted on it by a wire bonding process, that is compatible with the use of low-k dielectric materials for intermetal dielectric layers, and that will also allow circuitry and devices to be formed under the bond pad.

### SUMMARY OF THE INVENTION

The problems and needs outlined above may be addressed by embodiments of the present invention. In accordance with one aspect of the present invention, an integrated circuit chip is provided, which includes a bond pad structure, a low-k dielectric layer, and active circuits. The bond pad structure includes a conductive bond pad, an Mₜₒₚ solid conductive plate, and an Mₜₒₚ₋₁ solid conductive plate. The Mₜₒₚ solid conductive plate is located under the bond pad. The Mₜₒₚ plate is electrically coupled to the bond pad. The Mₜₒₚ₋₁ solid conductive plate is located under the Mₜₒₚ plate. The low-k dielectric layer is located under the bond pad of the bond pad structure. At least part of an active circuit is located under the bond pad of the bond pad structure.

In accordance with another aspect of the present invention, an integrated circuit chip is provided, which includes a bond pad structure, a low-k dielectric layer, and active circuits. The bond pad structure includes a conductive bond pad, an Mₜₒₚ solid conductive plate, and an Mₜₒₚ₋₁ solid conductive plate. The Mₜₒₚ solid conductive plate is located under the bond pad. The Mₜₒₚ plate is electrically coupled to the bond pad. The Mₜₒₚ plate has a top profile shape with an Mₜₒₚ plate area. The Mₜₒₚ₋₁ solid conductive plate is located under the Mₜₒₚ plate. The Mₜₒₚ₋₁ plate has a top profile shape with an Mₜₒₚ₋₁ plate area. The Mₜₒₚ₋₁ plate area is no less than about 60% of the Mₜₒₚ plate area. The low-k dielectric layer is located under the bond pad of the bond pad structure. At least part of an active circuit located under the bond pad of the bond pad structure.

In accordance with yet another aspect of the present invention, an integrated circuit chip is provided, which includes a first bond pad structure, a second bond pad structure, a low-k dielectric layer, and active circuits. The first bond pad structure includes a conductive bond pad, an Mₜₒₚ solid conductive plate, and an Mₜₒₚ₋₁ solid conductive plate. The Mₜₒₚ solid conductive plate is located under the bond pad. The Mₜₒₚ plate is electrically coupled to the bond pad. The Mₜₒₚ₋₁ solid conductive plate is located under the Mₜₒₚ plate. The low-k dielectric layer located under the bond pad of the first bond pad structure. At least part of an active circuit is located under the first bond pad structure. No active circuit is located under the second bond pad structure.

The foregoing has outlined rather broadly features of the present invention in order that the detailed description of the invention that follows may be better understood. Additional features and advantages of the invention will be described hereinafter, which form the subject of the claims of the invention. It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

The following is a brief description of the drawings, which illustrate exemplary embodiments of the present invention and in which:

FIG. 1 is a top view of an integrated circuit chip incorporating embodiments of the present invention;

FIG. 2 is an enlarged view of portion A from FIG. 1;

FIG. 3 is a cross-section view of a bond pad structure of the first embodiment, as taken along line 3-3 in FIG. 2;

FIG. 4 is a top sectional view showing an Mₜₒₚ metal level of the bond pad structure, as taken along line 4-4 in FIG. 3;

FIG. 5 is another top sectional view showing an Mₜₒₚ₋₁ metal level of the bond pad structure, as taken along line 5-5 in FIG. 3;

FIG. 6 is a cross-section view of the bond pad structure of the second embodiment, as taken along line 6-6 in FIG. 2;

FIG. 7 is a top sectional view showing the conductive vias located between the Mₜₒₚ plate and the Mₜₒₚ₋₁ plate, as taken along line 7-7 in FIG. 6;

FIG. 8 is an enlarged view of portion B shown in FIG. 1;

FIG. 9 is a cross-section view of two different bond pad structures of the third embodiment, as taken along line 9-9 in FIG. 8;

FIG. 10 is a top sectional view showing an Mₜₒₚ metal level of the two bond pad structures of the third embodiment, as taken along line 10-10 in FIG. 9;

FIG. 11 is another top sectional view showing an Mₜₒₚ₋₁ metal level of the two bond pad structures of the third embodiment, as taken along line 11-11 in FIG. 9;

FIG. 12 is a top sectional view showing an Mₜₒₚ₋₁ metal level of the two bond pad structures of the fourth embodiment, as taken along line 12-12 in FIG. 9; and

FIG. 13 is a cross-section view of the two bond pad structures of the fifth embodiment, as taken along line 13-13 in FIG. 8.

### DETAILED DESCRIPTION OF ILLUSTRATIVE EMBODIMENTS

Referring now to the drawings, wherein like reference numbers are used herein to designate like or similar elements throughout the various views, illustrative embodiments of the present invention are shown and described. The figures are not necessarily drawn to scale, and in some instances the drawings have been exaggerated and/or simplified in places for illustrative purposes only. One of ordinary skill in the art will appreciate the many possible applications and variations of the present invention based on the following illustrative embodiments of the present invention.

Generally, an embodiment of the present invention provides an improved bond pad structure for an integrated circuit chip. An embodiment of the present invention is preferably designed so that at least part of the integrated circuits or active circuits formed in a chip may be located under at least some of the bond pad structures. This is advantageous to maximize the real estate of a chip and/or to reduce chip size. Several embodiments of the present invention will be described herein, which may be used in the context of wire bonding or solder ball/bump grid array, for example. However, an embodiment of the present invention also may be applied in other contexts.

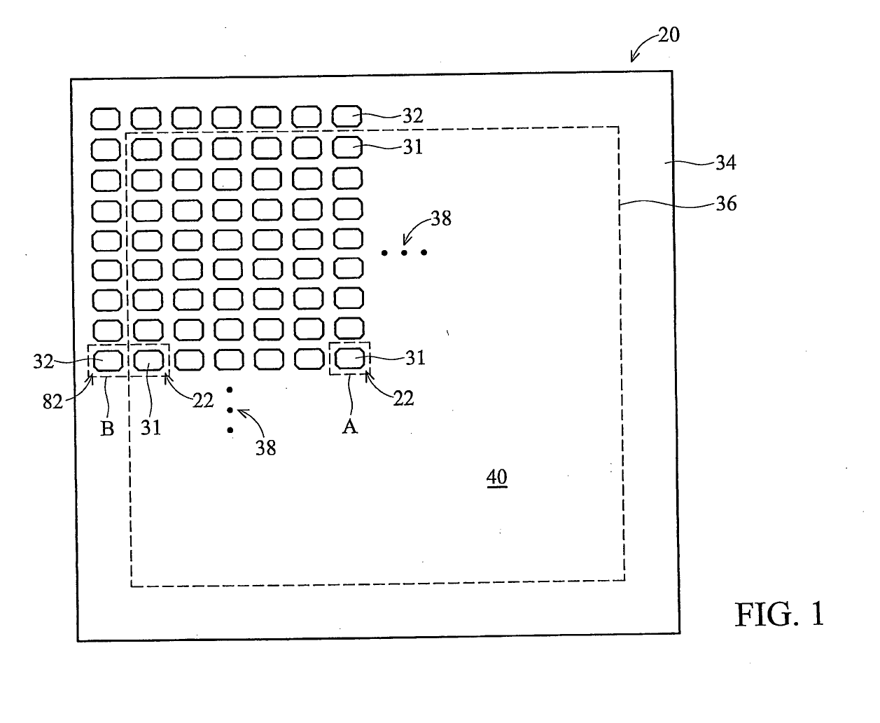

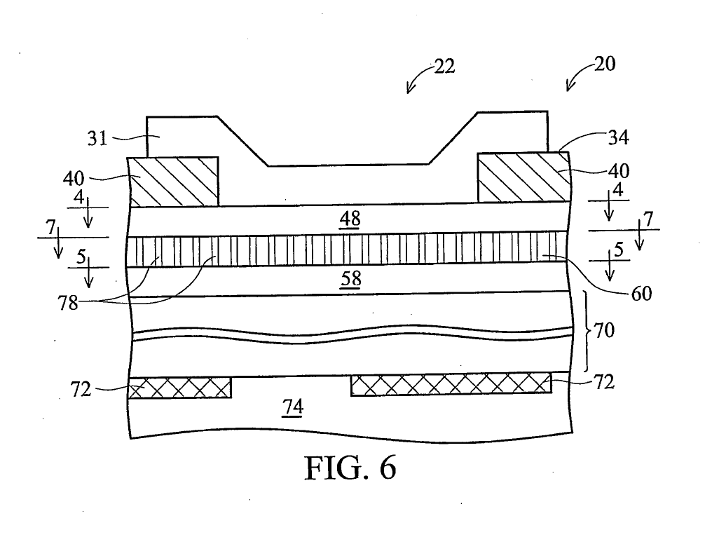

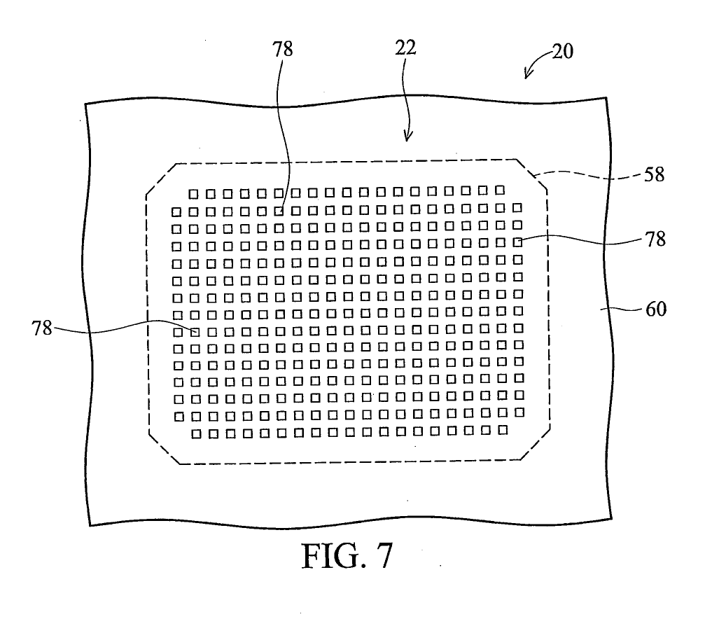

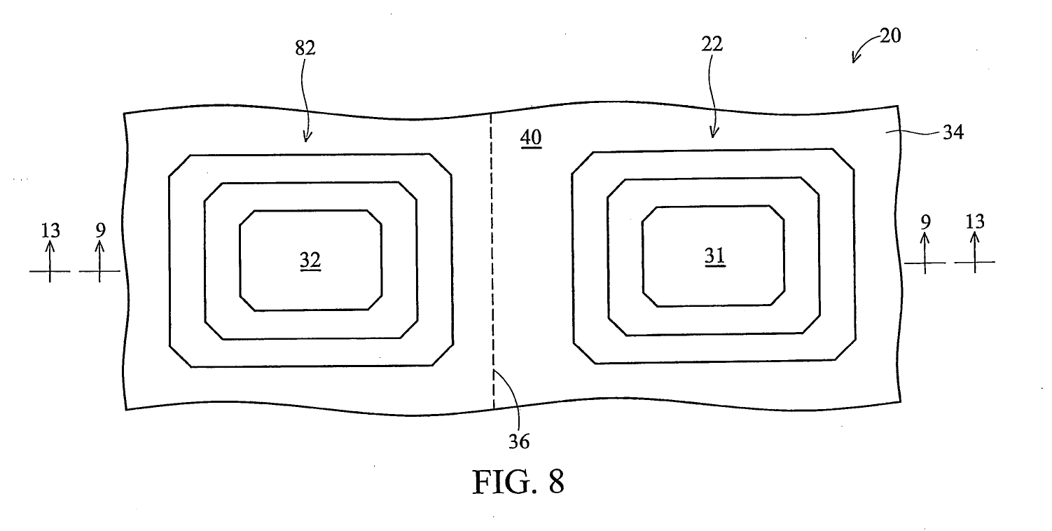

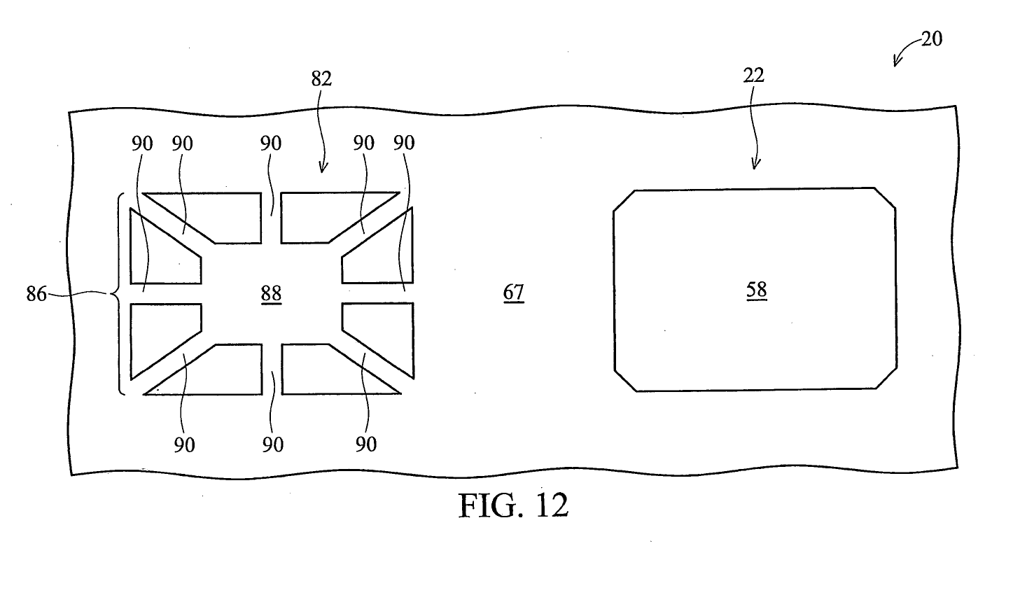

A first illustrative embodiment of the present invention will be described with respect to FIGS. 1-5. A second illustrative embodiment then will be described with respect to FIGS. 6 and 7. Thereafter, a third illustrative embodiment is described regarding FIGS. 8-11. Next, a fourth illustrative embodiment is described with respect to FIG. 12. Lastly, a fifth illustrative embodiment of the present invention will be described with reference to FIG. 13.

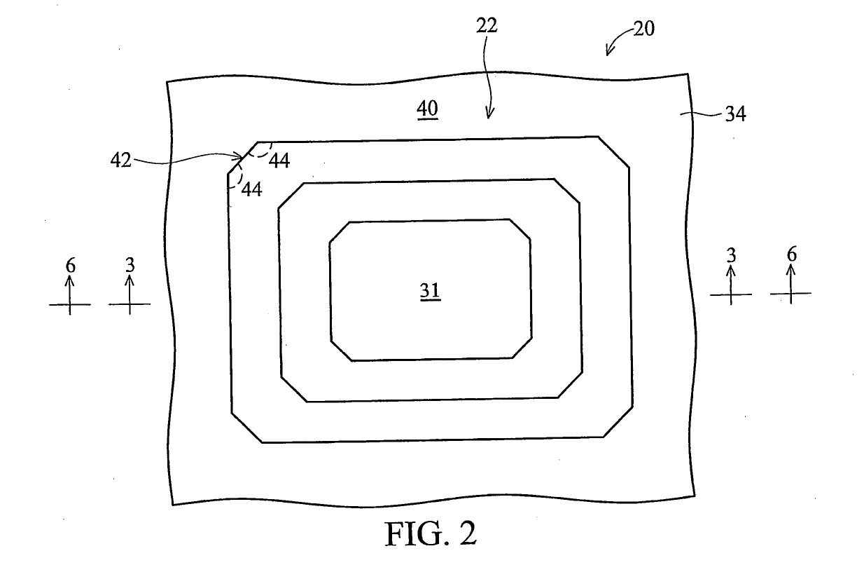

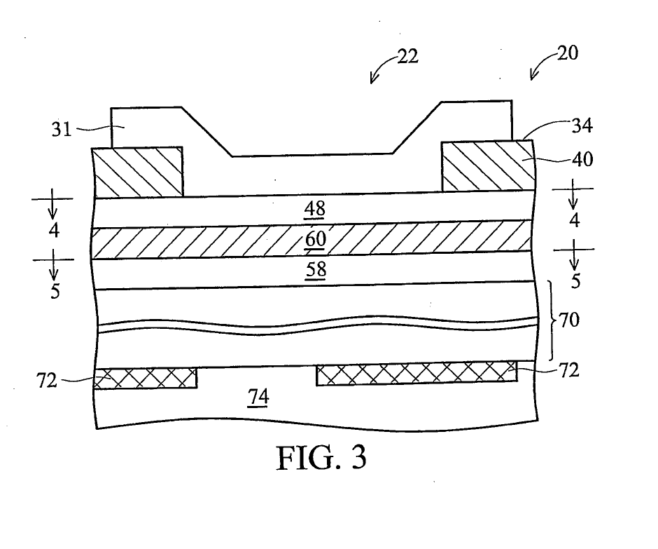

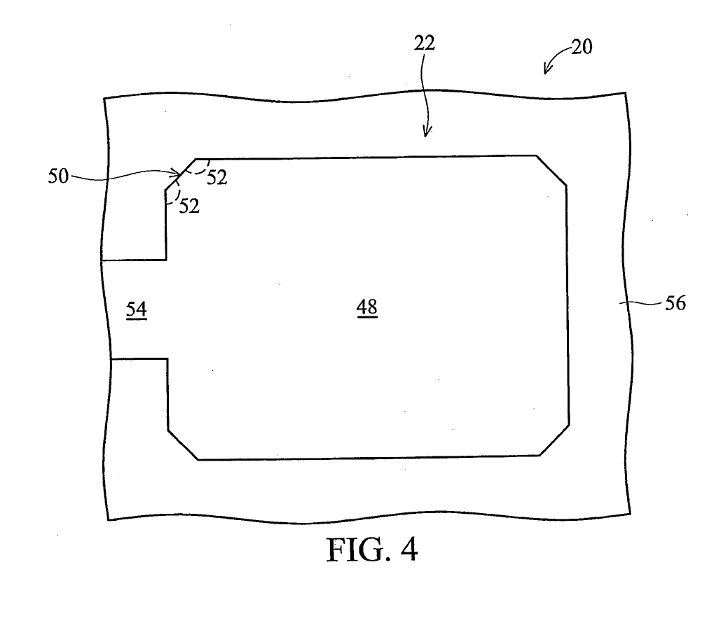

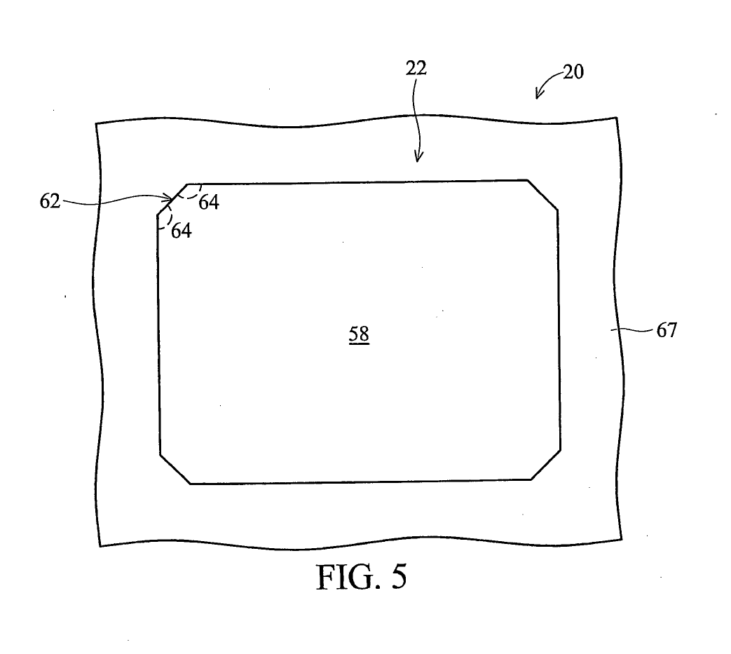

Referring now to FIGS. 1-5, various views of a first illustrative embodiment of the present invention are shown. More specifically, FIG. 1 is a top view of an integrated circuit chip 20 incorporating embodiments of the present invention. FIG. 2 is an enlarged view of portion A shown in FIG. 1. FIG. 3 is a cross-section view of a bond pad structure 22 of the first embodiment, as taken along line 3-3 in FIG. 2. FIG. 4 is a top sectional view showing an Mₜₒₚ metal level of the bond pad structure 22, as taken along line 4-4 in FIG. 3. FIG. 5 is another top sectional view showing an Mₜₒₚ₋₁ metal level of the bond pad structure 22, as taken along line 5-5 in FIG. 3.

Although FIG. 1 is referred to as a top view of the chip 20 herein showing the bond pads 31, 32 on the top surface 34 of the chip 20, the chip 20 may be operably mounted on a substrate (not shown) with the top surface 34 facing downward (e.g., flip chip bonding configuration). Hence, the term “top” is used herein as an arbitrarily chosen reference label that could be interchanged for the term bottom for other applications. In FIG. 1, the area under the top surface 34 where the active circuits are located is represented by active circuit area 36 bounded by dashed lines. Only some of the bond pads 31, 32 are shown in FIG. 1, and the ellipses 38 represent the repetition of more bond pads 31, 32, which are not shown for purposes of simplifying the illustration. Note that some of the bond pads 31, 32 in this example are located outside of the active circuit area 36. Thus, some of the bond pad structures may not be located over active circuits in an embodiment of the present invention, as will be discussed in more detail below. In other embodiments of the nresent invention (not shown). the number and placement of the bond pads may vary from that shown in the example chip 20 of FIG. 1. Although all of the bond pads 31, 32 shown in the example chip of FIG. 1 are the same in shape and size, the bond pads on a chip may have multiple shapes/sizes or a variety of shapes/sizes on a given chip for other embodiments (not shown).

FIG. 2 shows one of the bond pads 31 in portion A of FIG. 1. This bond pad 31 of FIG. 2 has a bond pad structure 22 in accordance with a first embodiment of the present invention, which will be described next. FIG. 3 shows a cross-section view of the bond pad structure 22 for the bond pad 31 of FIG. 2. The bond pad level of the bond pad structure 22 includes the conductive bond pad 31 and a passivation layer 40. Although the passivation layer 40 is shown as a single layer, in an actual application this passivation layer 40 may include any number (one or more) of layers and materials (e.g., composite, compound, stacked, etc.). Likewise, although the conductive bond pad 31 is shown as a single layer, in an actual application the bond pad 31 may include any number (one or more) of layers and materials (e.g., composite, compound, alloy, stacked, etc.).

The top profile shape of the bond pad 31 (see e.g., FIG. 2) preferably has a size of less than about 100 μm×100 μm, for example. In other embodiments (not shown), the bond pad 31 may have any shape and size. In a preferred embodiment, at least one of the corner regions 42 of the bond pad 31 (top profile shape) has corner angles 44 greater than 90 degrees, as shown in FIG. 2 for example. This shape reduces the stress risers at the corner regions 42 during a bonding process (e.g., wire bonding), as compared to a rectangular shape with 90 degree corners. Thus in a preferred embodiment, at least one of the corners of the bond pad is substantially free of bond material. Preferably, the corner regions 44 of the bond pad 31 (in the top profile shape) have increased angles or have curvatures to reduce stress concentrations about the bond pad 31. The bond pad 31 may be made from any of a wide variety of conductive materials, including (but not limited to): aluminum, gold, silver, nickel, copper, tungsten, titanium, tantalum, compounds thereof, alloys thereof, multiple layers thereof, composites thereof, and combinations thereof, for example.

Referring to FIG. 3, the bond pad structure 22 of the first embodiment has an Mₜₒₚ solid conductive plate 48 located under the bond pad 31. The Mₜₒₚ plate 48 is electrically coupled to the bond pad 31, as the bond pad 31 is formed on the Mₜₒₚ plate 48 in the first embodiment, for example. In other embodiments (not shown), there may be one or more layers intervening between the bond pad 31 and the Mₜₒₚ plate 48. FIG. 4 is a top sectional view showing the top profile shape of the Mₜₒₚ plate 48 of the bond pad structure 22, as taken along line 4-4 in FIG. 3. In the first embodiment, the top profile shape of the Mₜₒₚ plate 48 has an Mₜₒₚ plate area (see e.g., FIG. 4), which is no less than the bond pad area for the top profile shape of the bond pad 31 (see e.g., FIG. 2). Although it is preferred to have the Mₜₒₚ plate area being no less than the bond pad area, the Mₜₒₚ plate area may be the less than the bond pad area in other embodiments (not shown). Having the Mₜₒₚ plate area being no less than the bond pad area is advantageous for evenly distributing bonding stress exerted on the bond pad 31 as it is translated downward toward the active circuits. In a preferred embodiment, the Mₜₒₚ plate 48 of a bond pad structure 22 has a size of less than about 100 μm×100 μm, for example.

The Mₜₒₚ plate 48 of the first embodiment has a generally rectangular shape with notched corner regions 50 (see FIG. 4). Hence, the corner angles 52 at the corner regions 50 of the Mₜₒₚ plate 48 are greater than 90 degrees. This shape may reduce stress concentrations at the corner regions 50 during a bond process (e.g., wire bonding). In the first embodiment, a connection wire portion 54 extends from the Mₜₒₚ plate 48 for providing an electrical connection with the Mₜₒₚ plate 48. In other embodiments, the Mₜₒₚ plate 48 may have more than one connection wire portion 54 extending therefrom, or may have no connection wire portion. The top profile shape of the Mₜₒₚ plate 48 may vary for other embodiments and may be any shape. The Mₜₒₚ plate 48 is preferably made from copper. However, the Mₜₒₚ plate 48 may be made from any of a wide variety of suitable conductive materials, including (but not limited to): aluminum, gold, silver, nickel, copper, tungsten, titanium, tantalum, compounds thereof, alloys thereof, multiple layers thereof, composites thereof, and combinations thereof, for example. As shown in FIG. 4, the Mₜₒₚ plate 48 is at least partially surrounded by Mₜₒₚ dielectric material 56 at the Mₜₒₚ level.

Referring again to FIG. 3, an Mₜₒₚ₋₁ solid conductive plate 58 is located under the Mₜₒₚ plate 48. An Mₜₒₚ-to-Mₜₒₚ₋₁ intermetal dielectric laver 60 is located between the Mₜₒₚ plate 48 and the Mₜₒₚ₋₁ plate 58. The Mₜₒₚ-to-Mₜₒₚ₋₁ intermetal dielectric layer 60 is preferably made from undoped silicon glass (USG) to provide adequate strength at this level in the bond pad structure 22. In other embodiments, however, other suitable dielectric materials, including low-k dielectric materials, may be used in the Mₜₒₚ-to-Mₜₒₚ₋₁ intermetal dielectric layer 60. Although the Mₜₒₚ-to-Mₜₒₚ₋₁ intermetal dielectric layer 60 is shown as a single layer in FIG. 3, in an actual application Mₜₒₚ-to-Mₜₒₚ₋₁ intermetal dielectric layer 60 may include any number (one or more) of layers and materials (e.g., composite, compound, stacked, etc.).

FIG. 5 is a top sectional view showing the top profile shape of the Mₜₒₚ₋₁ plate 58 of the bond pad structure 22, as taken along line 5-5 in FIG. 3. The Mₜₒₚ₋₁ plate 58 of the first embodiment has a generally rectangular shape with notched corner regions 62 (see FIG. 5), essentially the same as that of the Mₜₒₚ plate 48 (but without the connection wire extension 54). Hence, the corner angles 64 of the corner regions 62 for the Mₜₒₚ₋₁ plate 58 are greater than 90 degrees. This shape may reduce stress concentrations at the corner regions 62 during a bonding process (e.g., wire bonding). Note that the Mₜₒₚ₋₁ plate 58 of the first embodiment is not electrically connected to anything and is thus a “dummy” plate provided mainly for structural strengthening. In other embodiments, the Mₜₒₚ₋₁ plate 58 may have one or more connection wire portions extending therefrom and may be electrically connected to an active circuit or a ground voltage. Also, as will be discussed below, the Mₜₒₚ₋₁ plate 58 may be electrically connected to the Mₜₒₚ plate 48 and/or the bond pad 31 in other embodiments. The top profile shape of the Mₜₒₚ₋₁ plate 58 may vary for other embodiments and may be any shape. The Mₜₒₚ₋₁ plate 58 is preferably made from copper. However, the Mₜₒₚ₋₁ plate 58 may be made from any of a wide variety of suitable conductive materials, including (but not limited to): aluminum, gold, silver, nickel, copper, tungsten, titanium, tantalum, compounds thereof, alloys thereof, multiple layers thereof, composites thereof, and combinations thereof, for example. As shown in FIG. 5, the Mₜₒₚ₋₁ plate 58 is at least partially surrounded by Mₜₒₚ₋₁ dielectric material 67 at the Mₜₒₚ₋₁ level.

The top profile shape of the Mₜₒₚ₋₁ plate 58 (see FIG. 5) has an Mₜₒₚ₋₁ plate area. In a preferred embodiment, the Mₜₒₚ₋₁ plate area is no less than about 60% of the Mₜₒₚ plate area. In other embodiments, however, the Mₜₒₚ₋₁ plate area may be less than 60% of the Mₜₒₚ plate area. In the first embodiment, the Mₜₒₚ₋₁ plate area is about the same as the Mₜₒₚ plate area (not counting the connection wire portion 54), and the Mₜₒₚ₋₁ plate shape is about the same as the Mₜₒₚ plate shape (not counting the connection wire portion 54). Having the Mₜₒₚ₋₁ plate area being no less than about 60% of the Mₜₒₚ plate area is advantageous for more evenly distributing bonding stress exerted on the bond pad 31 as stress is translated downward toward the active circuits there under.

Referring again to FIG. 3, one or more intermetal dielectric (IMD) layers 70 are located under the Mₜₒₚ₋₁ plate 58. Such IMD layer(s) 70 typically include conducting lines, vias, and/or wires (not shown for simplification) for the active circuits 72, which are shown there below. The active circuits 72 are typically formed on and/or in a semiconductor substrate 74 (e.g., silicon, strained silicon, germanium, SOI, etc.). The active circuits 72 are represented by rectangular blocks for purposes of simplifying the drawings. The active circuits 72 may include any of a wide variety of electrical or electronic devices, such as memory cells, logic devices, amplifiers, power converters, magnetic tunnel junction devices, transistors, diodes, resistors, capacitors, inductors, and combinations thereof, for example. The IMD layer(s) 70 include one or more layers of low-k dielectric material(s). Low-k dielectric materials are usually materials having a dielectric constant (k) less than about 4.0 and typically less than that of silicon dioxide (SiO₂). Low-k materials are typically porous, soft, and weak relative to SiO₂, and often have high thermal expansion rates and low thermal conductivity relative to neighboring structures and layers. Generally, as the dielectric constant (k) decreases for a low-k dielectric material, the structural strength of the material decreases as well. Yet, it is generally desired to use low-k dielectric materials in IMD layer(s) 70 with the lowest possible dielectric constant to reduce RC delay and parasitic capacitances. Preferred materials for the low-k dielectric layer(s) in the IMD layer(s) 70 include (but are not limited to): dielectric material with a dielectric constant (k) less than 3.0, dielectric material with a dielectric constant (k) less than 2.5, low-k dielectric material including Si, C, N, and O, porous low-k dielectric material, and combinations thereof, for example.

The combination of the solid Mₜₒₚ plate 48 and the solid Mₜₒₚ₋₁ plate 58 in the bond pad structure 22 has been found to be advantageous for limiting or greatlv reducing stress concentrations that reach the underlying low-k dielectric layer(s) of the IMD 70 and active circuits 72 during a bonding process. Thus, an embodiment of the present invention may permit at least part of an active circuit 72 to be located under a bond pad 31, while still using and obtaining the favorable electrical benefits of using low-k dielectric material(s) in the IMD layer(s) 70.

Referring now to FIGS. 1, 2, and 4-7, various views of a second illustrative embodiment of the present invention are shown. FIG. 6 is a cross-section view of the bond pad structure 22 of the second embodiment, as taken along line 6-6 in FIG. 2. The bond pad structure 22 of the second embodiment is essentially the same as that of the first embodiment (FIGS. 1-5), except that the second embodiment has conductive vias 78 added between the Mₜₒₚ plate 48 and the Mₜₒₚ₋₁ plate 58. In other words, the second embodiment is one possible variation (among many) of the first embodiment. Hence, the bond pad structure of the second embodiment (see e.g., FIG. 6) may be used in alternative to, in substitute for, or in combination with the bond pad structure of the first embodiment (see e.g., FIG. 3). The Mₜₒₚ plate 48 and the Mₜₒₚ₋₁ plate 58 of the second embodiment may be the same as that of the first embodiment described above (see e.g., FIGS. 4 and 5), or may differ.

FIG. 7 is a top sectional view showing the conductive vias 78 located between the Mₜₒₚ plate 48 and the Mₜₒₚ₋₁ plate 58, as taken along line 7-7 in FIG. 6. The conductive vias 78 may be formed from any of a variety of suitable conductive materials, including (but not limited to): aluminum, gold, silver, nickel, copper, tungsten, titanium, tantalum, compounds thereof, alloys thereof, multiple layers thereof, composites thereof, and combinations thereof, for example. In a preferred embodiment, the Mₜₒₚ plate 48 is electrically connected to the Mₜₒₚ₋₁ plate 58 by the conductive vias 78. In other embodiments, however, the Mₜₒₚ plate 48 may not be electrically connected to the Mₜₒₚ₋₁ plate 58 by the conductive vias 78 (e.g., separated by a nonconductive layer or portion). In a preferred embodiment, at least some of the conductive vias 78 have a width of less than about 1 μm, for example. In the second embodiment, the Mₜₒₚ₋₁ plate 58 is only electrically connected to the Mₜₒₚ plate 48 by the conductive vias 78, and the Mₜₒₚ₋₁ plate 58 along with the conductive vias 78 are used mainly for increasing structural strength. Hence, the conductive vias 78 may be considered “dummy” vias. In another embodiment (not shown), the Mₜₒₚ plate 48 may not have connection wire portion 54 extending therefrom in the Mₜₒₚ level and instead the Mₜₒₚ₋₁ plate 58 may have a connection wire portion extending from it, for example. In such case, the conductive vias 78 may be used to provide an electrical connection from the bond pad 31 to the Mₜₒₚ₋₁ plate 58 (via the Mₜₒₚ plate 48). Thus in such case, the conductive vias 78 and the Mₜₒₚ₋₁ plate 58 would not be “dummy” structures. It should be noted also that in other embodiments (not shown) the number, pattern, and placement of the conductive vias 78 may vary from that shown in FIGS. 6 and 7.

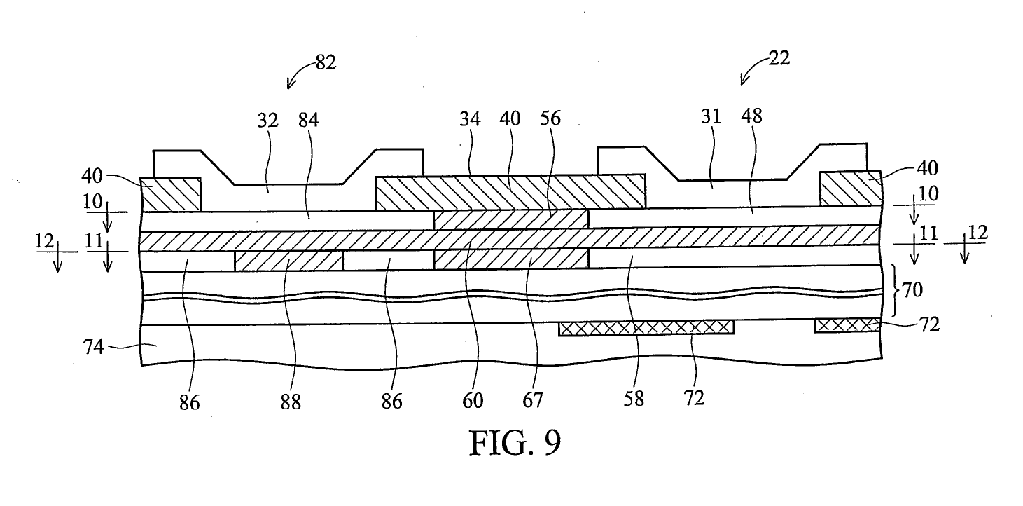

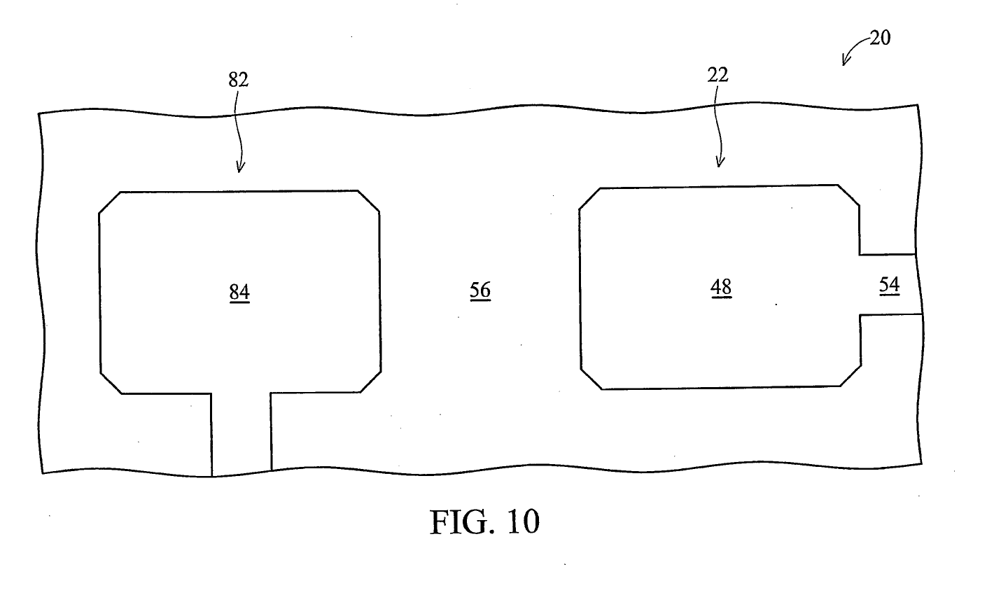

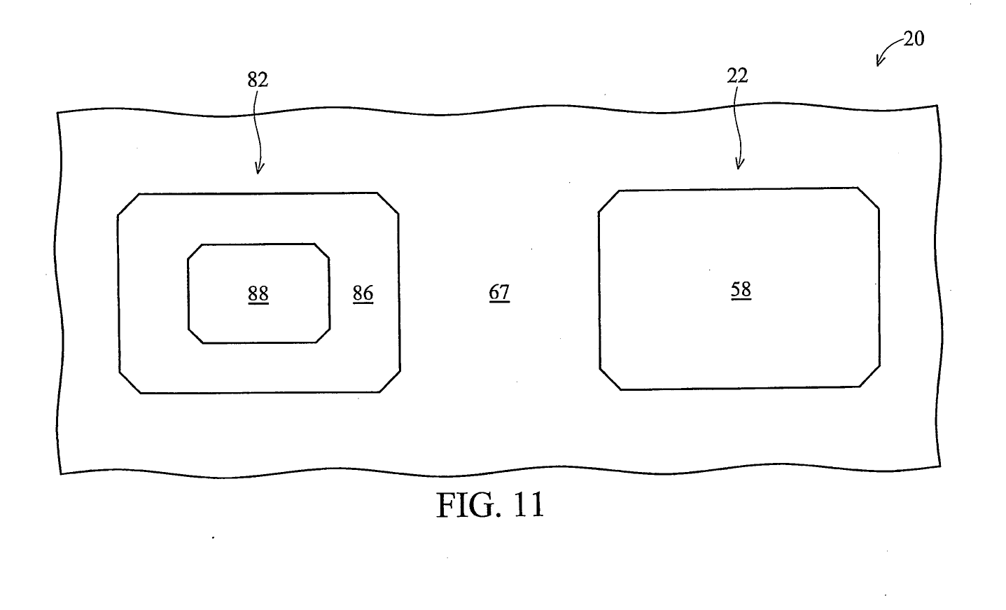

Referring now to FIGS. 1 and 8-11, various views of a third illustrative embodiment of the present invention are shown. More specifically, FIG. 8 is an enlarged view of portion B shown in FIG. 1. FIG. 9 is a cross-section view of two different bond pad structures 22, 82 of the third embodiment, as taken along line 9-9 in FIG. 8. FIG. 10 is a top sectional view showing an Mₜₒₚ metal level of the two bond pad structures 22, 82, as taken along line 10-10 in FIG. 9. FIG. 11 is another top sectional view showing an Mₜₒₚ₋₁ metal level of the two bond pad structures 22, 82, as taken along line 11-11 in FIG. 9.

The third embodiment focuses on an integrated chip 20 having a first bond pad structure 22 with at least part of at least one active circuit 72 located there under, and a second bond pad structure 82 with no active circuit there under. In some embodiments of the present invention (not shown), all of the bond pad structures may be located over the active circuit area. As shown in FIG. 9, the first bond pad structure 22 (adapted for being located over active circuits 72) differs from the second bond pad structure 82 (located outside of the active circuit area 36) in the third embodiment. In other embodiments (not shown), some or all of the bond pad structures located outside of the active circuit area 36 may be the same as some or all of the bond pad structures located over active circuits 72 (i.e., at least partially in the active circuit area 36).

Referring to FIG. 9, the first bond pad structure 22 is essentially the same as that of the first embodiment described above (see e.g., FIG. 3). The second bond pad structure 82 has a bond pad 32, which is the same as that of the first bond pad structure 22 in this case. The second bond pad structure 82 includes an Mₜₒₚ plate 84 and an Mₜₒₚ₋₁ plate 86. In the third embodiment, the Mₜₒₚ plate 84 of the second bond pad structure 82 is a solid conductive plate, and the Mₜₒₚ₋₁ plate 86 of the second bond pad structure 82 is a non-solid conductive portion located under the bond pad 32. In other embodiments, the Mₜₒₚ plate 84 and the Mₜₒₚ₋₁ plate 86 may be different than that of the third embodiment (shown in FIGS. 10 and 11). FIG. 10 shows a top view of the Mₜₒₚ plates 48, 84 of the first and second bond pad structures 22, 82. FIG. 11 shows a top view of the Mₜₒₚ₋₁ plates 58, 86 of the first and second bond pad structures 22, 82. As shown in FIGS. 9 and 11, a non-conductive portion 88 is located under the bond pad 32 and adjacent to the non-solid conductive portion 86 of the second bond pad structure 82, which may or may not be the same dielectric material as that which surrounds the non-solid conductive portion 86 at the Mₜₒₚ₋₁ level.

Referring now to FIGS. 1, 8-10, and 12, various views of a fourth illustrative embodiment of the present invention are shown. The bond pad structures 22, 82 of the fourth embodiment are essentially the same as that of the third embodiment (FIGS. 1 and 8-11), except that the fourth embodiment has slots 90 formed in the Mₜₒₚ₋₁ plate 86 for the second bond pad structure 82. FIG. 12 is a top sectional view showing an Mₜₒₚ₋₁ metal level of the two bond pad structures 22, 82 of the fourth embodiment, as taken along line 12-12 in FIG. 9. Hence, the second bond pad structure 82 of the fourth embodiment (see e.g., FIG. 6) may be used in alternative to, in substitute for, or in combination with the second bond pad structure 82 of the third embodiment (see e.g., FIG. 3). The Mₜₒₚ plate 48 and the Mₜₒₚ₋₁ plate 58 of first bond pad structure 22 in the fourth embodiment may be the same as that of the third embodiment described above (see e.g., FIGS. 10 and 11), or may differ.

Referring now to FIGS. 1, 8, 10, 11, and 13, various views of a fifth illustrative embodiment of the present invention are shown. The bond pad structures 22, 82 of the fifth embodiment are essentially the same as that of the third embodiment (FIGS. 1 and 8-11). except that the fifth embodiment has conductive vias 78, 92 added between the Mₜₒₚ plates 48, 84 and the Mₜₒₚ₋₁ plates 58, 86, respectively. FIG. 13 is a cross-section view of the two bond pad structures 22, 82 of the fifth embodiment, as taken along line 13-13 in FIG. 8. Hence, the bond pad structures 22, 82 of the fifth embodiment (see e.g., FIG. 13) may be used in alternative to, in substitute for, or in combination with the bond pad structures 22, 82 of the third embodiment (see e.g., FIG. 9). The Mₜₒₚ plates 48, 84 and the Mₜₒₚ₋₁ plates 58, 86 of the fifth embodiment may be the same as that of the third or fourth embodiments described above (see e.g., FIGS. 10 and 11), or may differ in any combination.

In an embodiment of the present invention, additional buffer layers (not shown) may be included in the bond pad structures 22, 82, as desired or needed. It is further noted that any aspects of the embodiments described herein may be mixed and combined in any feasibie combination to form other embodiments of the present invention, as will be apparent to one of ordinary skill in the having the benefit of this disclosure.

Advantages of an embodiment of the present invention may include (but are not necessarily limited to): 1) good bondability and 2) processing steps for formation that are comparable to currently known and/or currently used processes to allow for relatively inexpensive and relatively easy conversion to design rules that are in accordance with one or more embodiments or aspects of the present invention. With benefit of this disclosure, one of ordinary skill in the art will likely realize other advantages and benefits of implementing one or more embodiments or aspects of the present invention.

Although embodiments of the present invention and at least some of its advantages have been described in detail, it should be understood that various changes, substitutions, and alterations can be made herein without departing from the spirit and scope of the invention as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An integrated circuit chip comprising:
a first bond pad structure, the first bond pad structure comprising
a conductive bond pad,
an Mₜₒₚ solid conductive plate located under the bond pad, the Mₜₒₚ plate being electrically coupled to the bond pad, and
an Mₜₒₚ₋₁ solid conductive plate located under the Mₜₒₚ plate;
a low-k dielectric layer located under the bond pad of the first bond pad structure; and
at least part of an active circuit located under the bond pad of the first bond pad structure.

2. The chip of claim 1, wherein the Mₜₒₚ plate of the first bond pad structure has a top profile shape with an Mₜₒₚ plate area, wherein the Mₜₒₚ₋₁ plate of the first bond pad structure has a top profile shape with an Mₜₒₚ₋₁ plate area, and wherein the Mₜₒₚ₋₁ plate area is no less than about 60% of the Mₜₒₚ plate area.

3. The chip of claim 2, wherein the bond pad of the first bond pad structure has a top profile shape with a bond pad area, and wherein the Mₜₒₚ plate area is no less than the bond pad area.

4. The chip of claim 3, wherein the top profile shape of the bond pad in the first bond pad structure has a size of less than about 100 μm×about 100 μm.

5. The chip of claim 1, wherein the first bond pad structure further comprises a plurality of conductive vias located between the Mₜₒₚ plate and the Mₜₒₚ₋₁ plate and that electrically connect the Mₜₒₚ plate and the Mₜₒₚ₋₁ plate.

6. The chip of claim 5, wherein the conductive vias have a width of less than about 1 μm.

7. The chip of claim 1, wherein the first bond pad structure further comprises multiple dielectric layers located between the bond pad and the active circuit.

8. The chip of claim 1, wherein at least one corner of the bond pad has corner angles greater than 90 degrees.

9. The chip of claim 1, wherein the bond pad is formed on the Mₜₒₚ plate.

10. The chip of claim 1, further comprising a second bond pad structure, wherein no active circuit is located under the second bond pad structure.

11. The chip of claim 10, wherein the second bond pad structure differs from the first bond pad structure.

12. The chip of claim 11, wherein the second bond pad structure comprises:
a second conductive bond pad; and
a non-solid conductive portion located under the second bond pad.

13. The chip of claim 12, wherein the second bond pad structure comprises:
a non-conductive portion located under the second bond pad and adjacent to the non-solid conductive portion, the non-conductive portion having a size of less than about 100 μm×about 100 μm.

14. The chip of claim 12, wherein the non-solid conductive portion comprises a slot formed therein.

15. The chip of claim 12, wherein the non-solid conductive portion comprises a hollow portion formed therein.

16. The chip of claim 10, wherein the second bond pad structure is a substantially same layout as that of the first bond pad structure.

17. An integrated circuit chip comprising:
a bond pad structure comprising
a conductive bond pad,
an Mₜₒₚ solid conductive plate located under the bond pad, the Mₜₒₚ plate being electrically coupled to the bond pad, the Mₜₒₚ plate having a top profile shape with an Mₜₒₚ plate area, and
an Mₜₒₚ₋₁ solid conductive plate located under the Mₜₒₚ plate, the Mₜₒₚ₋₁ plate having a top profile shape with an Mₜₒₚ₋₁ plate area, the Mₜₒₚ₋₁ plate area being no less than about 60% of the Mₜₒₚ plate area;
a low-k dielectric layer located under the bond pad of the bond pad structure; and
at least part of an active circuit located under the bond pad of the bond pad structure.

18. The chip of claim 17, wherein the bond pad has a top profile shape with a bond pad area, and wherein the Mₜₒₚ plate area is no less than the bond pad area.

19. The chip of claim 18, wherein the top profile shape of the bond pad has a size of less than about 100 μm×about 100 μm.

20. The chip of claim 17, further comprising a plurality of conductive vias located between the Mₜₒₚ plate and the Mₜₒₚ₋₁ plate and that electrically connect the Mₜₒₚ plate and the Mₜₒₚ₋₁ plate.

21. The chip of claim 20, wherein the conductive vias have a width of less than about 1 μm.

22. The chip of claim 17, wherein the bond pad structure further comprises multiple dielectric layers located between the bond pad and the active circuit.

23. An integrated circuit chip comprising:
a first bond pad structure, the first bond pad structure comprising
a conductive bond pad,
an Mₜₒₚ solid conductive plate located under the bond pad, the Mₜₒₚ plate being electrically coupled to the bond pad, and
an Mₜₒₚ₋₁ solid conductive plate located under the Mₜₒₚ plate;
a low-k dielectric layer located under the bond pad of the first bond pad structure; and
a second bond pad structure,
wherein at least part of an active circuit is located under the first bond pad structure, and
wherein no active circuit is located under the second bond pad structure.

24. The chip of claim 23, wherein the second bond pad structure differs from the first bond pad structure.

25. The chip of claim 24, wherein the second bond pad structure comprises:
a second conductive bond pad; and
a non-solid conductive portion located under the second bond pad.

26. The chip of claim 25, wherein the second bond pad structure comprises:
a non-conductive portion located under the second bond pad and adjacent to the non-solid conductive portion, the non-conductive portion having a size of less than about 100 μm×about 100 μm.

27. The chip of claim 25, wherein the non-solid conductive portion comprises a slot formed therein.

28. The chip of claim 25, wherein the non-solid conductive portion comprises a hollow portion formed therein.

29. The chip of claim 23, wherein the second bond pad structure is a substantially same layout as that of the first bond pad structure.
